(19) United States
(12) Patent Application Publication
(10) Pub. No.: US 2024/0202606 A1
(43) Pub. Date: Jun. 20, 2024

(54) INFORMATION PROCESSING METHOD, INFORMATION PROCESSING APPARATUS, AND SUBSTRATE PROCESSING SYSTEM

(71) Applicant: Tokyo Electron Limited, Tokyo (JP)

(72) Inventors: Yukiya SAITOU, Sapporo City (JP); Yuki KATAOKA, Sapporo City (JP)

(73) Assignee: Tokyo Electron Limited, Tokyo (JP)

(21) Appl. No.: 18/589,462

(22) Filed: Feb. 28, 2024

Related U.S. Application Data
(63) Continuation of application No. PCT/JP2022/030707, filed on Aug. 12, 2022.

(30) Foreign Application Priority Data
Aug. 31, 2021 (JP) 2021-141749

(51) Int. Cl. G06N 20/20

(52) U.S. Cl. CPC G06N 20/20

(57) ABSTRACT

To provide an information processing method, an information processing apparatus, and a substrate processing system. Acquiring time series data from a plurality of types of sensors having different sampling periods provided in a substrate processing apparatus, performing learning of first learning models that output information relating to the substrate processing apparatus in a case where the time series data from the sensors are input, using each of the pieces of time series data having different sampling periods for each of the sensors individually, and inputting the time series data from the sensors into the corresponding first learning models after learning to output an estimation result based on information obtained from the first learning models are included.

### CROSS-REFERENCE TO RELATED APPLICATIONS

This application is a bypass continuation application of International Application No. PCT/JP2022/030707 having an international filing date of Aug. 12, 2022 and designating the United States, the international application being based upon and claiming the benefit of priority from Japanese Patent Application No. 2021-141749, filed on Aug. 31, 2021, the entire contents of each are incorporated herein by reference.

### TECHNICAL FIELD

The present invention relates to an information processing method, an information processing apparatus, and a substrate processing system.

### BACKGROUND

In a substrate processing system, a plurality of edge devices are used, and various processes are executed in various types of chambers having the plurality of edge devices.

For example, following documents disclose methods for managing machine learning models.
Patent Document 1: WO2018/173121
Patent Document 2: WO2019/163823

### SUMMARY

The present disclosure has been made in view of the above-described circumstances, and provides an information processing method, an information processing apparatus, and a substrate processing system capable of efficiently creating and managing models applied to various edge devices provided in the substrate processing system.

An information processing method according to an embodiment of the present invention includes acquiring time series data from a plurality of types of sensors having different sampling periods provided in a substrate processing apparatus, performing learning of first learning models that output information relating to the substrate processing apparatus in a case where the time series data from the sensors are input, using each of the pieces of time series data having different sampling periods for each of the sensors individually, and inputting the time series data from the sensors into the corresponding first learning models after learning to output an estimation result based on information obtained from the first learning models.

According to the present disclosure, it is possible to efficiently create and manage inference models of various edge devices provided in the substrate processing system.

### BRIEF DESCRIPTION OF DRAWINGS

FIG. 1 is a diagram illustrating a configuration example of a substrate processing system according to an embodiment.

FIG. 2 is a schematic diagram illustrating a configuration of a drive system of a substrate processing apparatus.

FIG. 3 is a cross-sectional view illustrating a configuration example of a chamber.

FIG. 4 is a block diagram illustrating a configuration of a control system of the substrate processing apparatus.

FIG. 5 is a block diagram illustrating an internal configuration of an edge device provided in the substrate processing apparatus.

FIG. 6 is a schematic diagram illustrating a configuration example of an observation model provided in the edge device.

FIG. 7 is a schematic diagram illustrating a configuration example of a control model provided in the edge device.

FIG. 8 is a block diagram illustrating an internal configuration of a control device provided in the substrate processing apparatus.

FIG. 9 is a conceptual diagram illustrating a configuration example of a database.

FIG. 10 is a block diagram illustrating an internal configuration of an apparatus group server.

FIG. 11 is a conceptual diagram illustrating a configuration example of a database.

FIG. 12 is a flowchart illustrating a procedure for generating a first learning model by the edge device.

FIG. 13 is a flowchart illustrating a procedure of processing executed in the substrate processing apparatus in an operational phase.

FIG. 14 is a flowchart illustrating a procedure of processing executed between the substrate processing apparatus and the apparatus group server in the operational phase.

FIG. 15 is a schematic diagram illustrating a display example of evaluation results.

### DETAILED DESCRIPTION

Hereinafter, an embodiment will be described with reference to the drawings. In the description, the same elements or elements having the same function are denoted by the same reference numerals, and overlapping descriptions thereof will be omitted.

### Embodiment 1

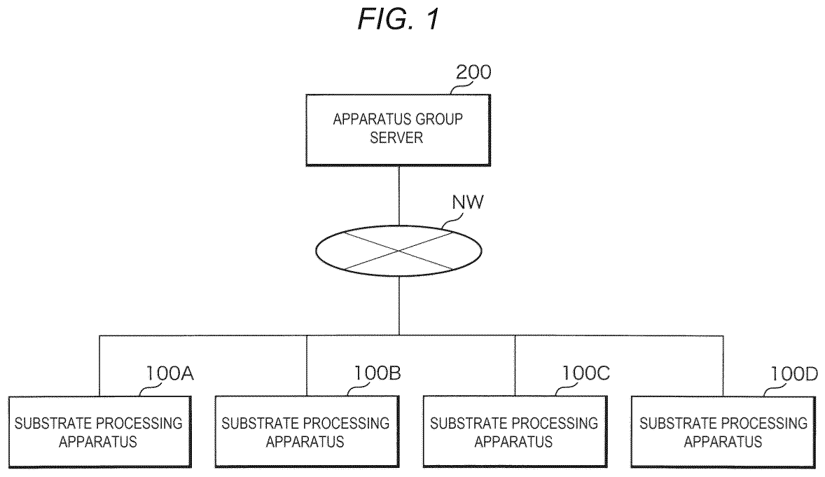

FIG. 1 is a diagram illustrating a configuration example of a substrate processing system according to an embodiment. The substrate processing system according to the embodiment is a system for managing a learning model applied to a plurality of substrate processing apparatuses 100A to 100D. The substrate processing system includes the plurality of substrate processing apparatuses 100A to 100D, and an apparatus group server 200 that collects data from the plurality of substrate processing apparatuses 100A to 100D. The substrate processing apparatuses 100A to 100D and the apparatus group server 200 are communicably connected to each other via a communication network NW such as a local area network (LAN) or a dedicated line.

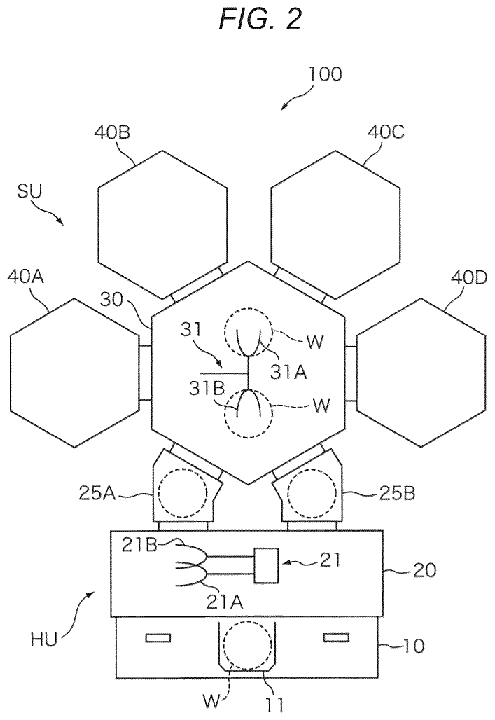

In the present embodiment, although the substrate processing system includes four substrate processing apparatuses 100A to 100D, the number of apparatuses is not limited to four. In the following description, in a case where there is no need to distinguish the substrate processing apparatuses 100A to 100D from each other, the apparatuses will also be referred to as a substrate processing apparatus 100 (refer to FIG. 2). In the present embodiment, the apparatus group server 200 may be a single computer, or may be a computer system including a plurality of computers, peripheral devices, or the like. In addition, the apparatus group server 200 may be a virtual machine in which entities are virtualized, or may be a cloud.

FIG. 2 is a schematic diagram illustrating a configuration of a drive system of the substrate processing apparatus 100. The substrate processing apparatus 100 includes a transfer unit HU for loading in and out a substrate W, and a processing unit SU that performs substrate processing on the substrate W.

The transfer unit HU includes a cassette stage 10 and a transfer stage 20. The cassette stage 10 includes a cassette container 11. The cassette container 11 accommodates, for example, up to 25 substrates W in a stacked state.

The transfer stage 20 includes a substrate transfer mechanism 21 for transferring the substrate W. The substrate transfer mechanism 21 includes two transfer arms 21A and 21B that hold the substrate W substantially horizontally. The substrate transfer mechanism 21 takes out the substrates W one by one from the cassette container 11 using the transfer arms 21A and 21B. The substrate transfer mechanism 21 transfers the substrate W taken out from the cassette container 11 to either load-lock chambers 25A and 25B. The load-lock chambers 25A and 25B connect the transfer unit HU to the processing unit SU.

The processing unit SU includes a transfer chamber 30 and four chambers 40A to 40D. The transfer chamber 30 has, for example, a sealable structure formed in a polygonal shape (in the illustrated example, a hexagonal shape) when viewed from above. The transfer chamber 30 is connected to each of the chambers 40A to 40D through an airtightly sealable gate valve. The transfer chamber 30 includes a substrate transfer mechanism 31 for transferring the substrate W. The substrate transfer mechanism 31 includes two transfer arms 31A and 31B that hold the substrate W substantially horizontally. The substrate transfer mechanism 31 takes out the substrate W from the load-lock chambers 25A and 25B using the transfer arms 31A and 31B, and transfers the taken substrate W to any one of the chambers 40A to 40D.

With this configuration, the processing unit SU transfers the substrate W transferred to the load-lock chambers 25A and 25B into the chambers 40A to 40D through the transfer chamber 30, and executes the substrate processing in the chambers 40A to 40D. After the substrate processing is executed, the processing unit SU takes out the processed substrate W from the chambers 40A to 40D, and unloads the taken substrate W to the load-lock chambers 25A and 25B through the transfer chamber 30. Examples of the substrate processing executed by the chambers 40A to 40D include film formation processing by chemical vapor deposition (CVD) or the like. Alternatively, the substrate processing executed by the chambers 40A to 40D may be diffusion processing, etching processing, ashing processing, sputtering processing, or the like. In addition, in the example of FIG. 2, a single-wafer type substrate processing apparatus 100 in which the substrates W are taken out one by one from the cassette container 11 and subjected to substrate processing is illustrated. However, the substrate processing apparatus 100 may be a batch type substrate processing apparatus or the like that processes a plurality of substrates W at the same time, and the transfer unit HU may adopt any configuration.

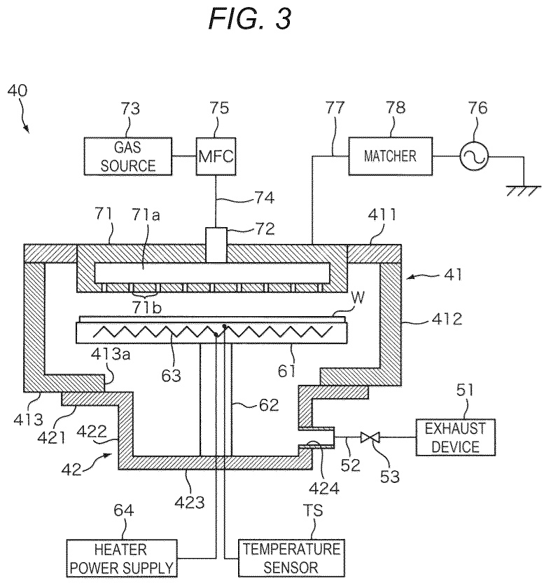

In the following description, in a case where it is not necessary to separately describe each of the chambers 40A to 40D, the chambers will also be simply referred to as a chamber 40 (refer to FIG. 3).

FIG. 3 is a cross-sectional view illustrating a configuration example of the chamber 40. The chamber 40 illustrated as an example in FIG. 3 is a device for performing film formation processing on the substrate W, and includes a processing chamber 41 in which the substrate processing is executed, and an exhaust chamber 42 communicating with the processing chamber 41.

The processing chamber 41 includes a plate-shaped ceiling portion 411 and a bottom portion 413, and a sidewall portion 412 that connects the ceiling portion 411 and the bottom portion 413. The processing chamber 41 has, for example, a substantially cylindrical shape. The sidewall portion 412 has a loading/unloading port for loading/unloading the substrate W to and from the transfer chamber 30. When a gate valve provided between the processing chamber 41 and the transfer chamber 30 is opened, the substrate W can be loaded and unloaded through the loading/unloading port. An opening 413a is formed in the center of the bottom portion 413. The exhaust chamber 42 is connected to the bottom portion 413 of the processing chamber 41 to communicate with the opening 413a.

The exhaust chamber 42 includes an annular flange portion 421, a plate-shaped bottom portion 423, and a sidewall portion 422 that connects the flange portion 421 and the bottom portion 423. The flange portion 421 is connected to the bottom portion 413 of the processing chamber 41. An exhaust hole 424 is formed in the sidewall portion 422.

The processing chamber 41 and the exhaust chamber 42 are configured such that an interior space thereof can be maintained in a vacuum environment (vacuum state). An O-ring serving as a sealing member is interposed between the joining portion of the processing chamber 41 and the exhaust chamber 42 and the joining portion of each member constituting the processing chamber 41 and the exhaust chamber 42 to ensure the airtightness of the joining portion.

The chamber 40 includes an exhaust device 51 disposed outside the processing chamber 41 and the exhaust chamber 42, an exhaust pipe 52 connecting the exhaust hole 424 and the exhaust device 51, and a valve 53 provided in the middle of the exhaust pipe 52. The valve 53 maintains the airtightness of the processing chamber 41 and the exhaust chamber 42 in a closed state, and enables the processing chamber 41 and the exhaust chamber 42 to be decompressed by the exhaust device 51 in an open state. The interior spaces of the processing chamber 41 and the exhaust chamber 42 are decompressed to the required vacuum level by operating the exhaust device 51.

The chamber 40 includes a susceptor 61 disposed in the processing chamber 41, and a support member 62 that supports the susceptor 61 in the processing chamber 41 and the exhaust chamber 42. The susceptor 61 is a substrate stage for horizontally supporting the substrate W. The susceptor 61 has a substrate placing surface (upper surface) on which the substrate W is placed, and a lower surface on the opposite side thereof. One end portion of the support member 62 is fixed to the central portion of the lower surface of the susceptor 61. The other end portion of the support member 62 is fixed to the bottom portion 423 of the exhaust chamber 42.

Although not illustrated, the susceptor 61 includes a plurality of support pins that are provided to protrude above and retract below the substrate placing surface. The plurality of support pins are configured to be vertically displaced by any elevation mechanism, and to transfer the substrate W to and from the substrate transfer mechanism 31 at the raised position.

The chamber 40 includes a heater 63, a heater power supply 64, and a temperature sensor TS. The heater 63 and the temperature measurement portion of the temperature sensor TS are embedded in the susceptor 61. The heater power supply 64 is disposed outside the processing chamber 41 and the exhaust chamber 42. The heater 63 is connected to the heater power supply 64 through, for example, a wiring passing through the inside of the support member 62. The heater power supply 64 supplies an electric output for heating the substrate W placed on the susceptor 61 to a desired temperature to the heater 63. The temperature of the susceptor 61 is measured by the temperature sensor TS. The temperature sensor TS is configured using a known member such as a thermocouple or a thermistor.

The chamber 40 includes a shower head 71 provided in the ceiling portion 411 of the processing chamber 41. The shower head 71 includes a gas diffusion space 71a formed therein, and a plurality of gas discharge holes 71b formed to penetrate from the gas diffusion space 71a toward the susceptor 61.

The chamber 40 includes a gas introduction pipe 72 provided on the opposite side to the plurality of gas discharge holes 71b in the shower head 71 and communicating with the gas diffusion space 71a, a gas source 73 disposed outside the processing chamber 41 and the exhaust chamber 42; a gas pipe 74 connecting the gas introduction pipe 72 and the gas source 73, a mass flow controller (MFC) 75 provided in the middle of the gas pipe 74, and a valve (not illustrated). The gas source 73 supplies, to the shower head 71, a film formation source gas used for film formation processing, a cleaning gas for cleaning the inside of the processing chamber 41 and the exhaust chamber 42, a purge gas for replacing the atmosphere in the processing chamber 41 and the exhaust chamber 42, and the like. These gases are supplied to the gas diffusion space 71a through the gas pipe 74 and the gas introduction pipe 72, and are discharged into the processing chamber 41 from the plurality of gas discharge holes 71b.

The chamber 40 includes a radio-frequency power supply 76 disposed outside the processing chamber 41 and the exhaust chamber 42, a wiring 77 that connects the shower head 71 and the radio-frequency power supply 76, and a matcher 78 provided in the middle of the wiring 77. The radio-frequency power supply 76 supplies radio-frequency power for converting the film formation source gas supplied into the processing chamber 41 into plasma to the shower head 71.

With the configuration described above, in the chamber 40, it is possible to perform film formation processing on the substrate W placed on the susceptor 61. That is, the substrate W that is a processing target is transferred into the processing chamber 41 in a vacuum state, the substrate W placed on the susceptor 61 is heated by the heater 63, and a source gas is supplied from the shower head 71 toward the substrate W, so that a thin film is formed on the surface of the substrate W. In order to promote a film formation reaction, the radio-frequency power may be supplied from the radio-frequency power supply 76 to the shower head 71. In this case, it becomes possible to form a film by converting a source gas supplied into the processing chamber 41 through the shower head 71 into plasma.

In the example of FIG. 3, although the chamber 40 subjected to the film formation processing on the substrate W is described, the chamber 40 may be a process module subjected to diffusion processing, etching processing, ashing processing, sputtering processing, or the like on the substrate W.

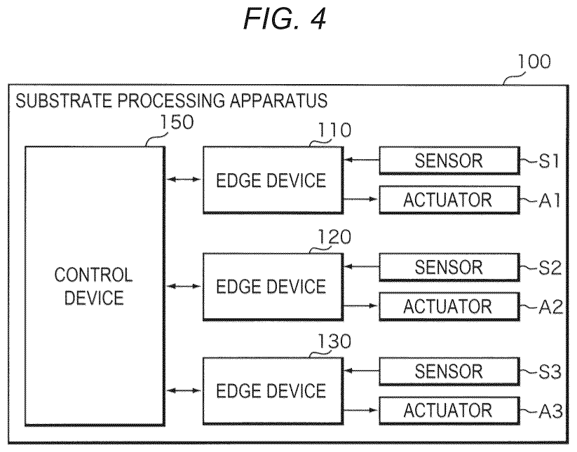

FIG. 4 is a block diagram illustrating a configuration of a control system of the substrate processing apparatus 100. The substrate processing apparatus 100 includes various types of sensors S1 to S3, edge devices 110 to 130 to which data output from the sensors S1 to S3 are input, actuators A1 to A3 controlled by each of the edge devices 110 to 130, and a control device 150 that controls the operation of the entire apparatus.

The sensors S1 to S3 are sensors provided in the substrate processing apparatus 100 and that measure physical quantities which are measurement targets in time series. The sensors S1 to S3 output time series data indicative of measurement results (hereinafter, also referred to as sensor data) to the subsequent edge devices 110 to 130.

An example of the sensor S1 is a radio frequency (RF) sensor. The RF sensor is installed at the output side of the radio-frequency power supply 76, and measures the RF power of the radio-frequency power supply 76 in time series. Alternatively, the RF sensor may be a sensor that measures voltage, current, capacitance, impedance, phase, load power, or the like in time series. An example of the sensor S2 is a temperature sensor. The temperature sensor includes the temperature sensor TS in which a temperature measurement portion is embedded in the susceptor 61, and measures the temperature of the substrate placing surface (that is, the temperature of the substrate W that is a processing target) in time series. Alternatively, the temperature sensor may be a sensor that measures the electrode temperature, the internal temperature of the processing chamber 41, or the like in time series. An example of the sensor S3 is a torque sensor. The torque sensor measures the torque that is received by the actuator (for example, actuator A3) installed in the substrate transfer mechanisms 21 and 31 in time series.

The sensors S1 to S3 installed in the substrate processing apparatus 100 are not limited to the RF sensor, the temperature sensor, and the torque sensor described above. In addition, the number of sensors installed in the substrate processing apparatus 100 is not limited to three. For example, the substrate processing apparatus 100 may include one or more sensors including a gas sensor, an optical emission spectroscopy (OES) sensor, a flow rate sensor, and the like. Here, the gas sensor is a sensor installed in the processing chamber 41 and measures the specific component amount of the gas filling the inside of the processing chamber 41 in time series. A mass spectrometer, an infrared spectrometer, a gas chromatography, or the like is used as the gas sensor. The OES sensor is a sensor installed in the processing chamber 41 and measures plasma emission intensity inside the processing chamber 41 in time series. The flow rate sensor is a sensor installed in the processing chamber 41 and measures the flow rate of a gas introduced into the inside of the processing chamber 41 in time series.

The sampling rates of the sensors S1 to S3 are random, and are appropriately set for each sensor. For example, the sampling rate of the RF sensor is 1 to 10 μsec. The sampling rate of the temperature sensor is, for example, 100 msec. The sampling rate of the torque sensor is, for example, 2.5 msec. The sampling rate of the OES sensor is, for example, 10 to 100 msec. The sampling rate of the gas sensor is, for example, 1 to 10 msec. The sampling rate of the flow rate sensor is, for example, 10 msec.

The edge devices 110 to 130 execute processing for estimating the state of the substrate processing apparatus 100, processing for estimating control values for the actuators A1 to A3, and the like, based on sensor data input from the sensors 51 to S3. For example, the edge devices 110 to 130 output estimation results of states to the control device 150, and control the operations of the actuators A1 to A3 based on the estimation results of the control values. The internal configuration of the edge devices 110 to 130 and the details of the processing executed by the edge device 110 will be described in detail later.

The actuators A1 to A3 are control targets of the edge devices 110 to 130. In this embodiment, various types of drive circuits including electric circuits will be collectively referred to as actuators, without being limited to a mechanical element such as motor that converts electrical energy into physical momentum.

For example, in a case where the sensor S1 is an RF sensor, the actuator A1 may be the radio-frequency power supply 76. In this case, the edge device 110 acquires time series data of the RF power from the RF sensor, estimates a control value for the radio-frequency power supply 76 based on the acquired time series data, and controls the operation of the radio-frequency power supply 76 based on the estimated control value. In addition, in a case where the sensor S2 is the temperature sensor TS, the actuator A2 may be the heater power supply 64. In this case, the edge device 120 acquires time series data of temperature from the temperature sensor TS, estimates a control value for the heater power supply 64 based on the acquired time series data, and controls the operation of the heater power supply 64 based on the estimated control values. Furthermore, in a case where the sensor S3 is a torque sensor, the actuator A3 may be a motor provided in the substrate transfer mechanisms 21 and 31. In this case, the edge device 130 acquires time series data of the torque received by a motor driving shaft from the torque sensor, estimates control values for the substrate transfer mechanisms 21 and 31 based on the acquired time series data, and controls the operations of the substrate transfer mechanisms 21 and 31 based on the estimated control values.

In the present embodiment, although each of the sensor and the actuator is connected to each of the edge devices 110 to 130 one by one, the number of sensors and actuators connected to each of the edge devices 110 to 130 is not limited to one. A plurality of sensors and a plurality of actuators may be connected to each of the edge devices 110 to 130. In addition, in the present embodiment, although the substrate processing apparatus 100 is configured to include three edge devices 110 to 130, the number of edge devices installed in the substrate processing apparatus 100 is not limited to three, and may include one or more edge devices.

The control device 150 controls the overall operation of the substrate processing apparatus 100 based on various information input from the edge devices 110 to 130 and various information input from the outside. The internal configuration of the control device 150 and the details of the processing executed by the control device 150 will be described in detail later.

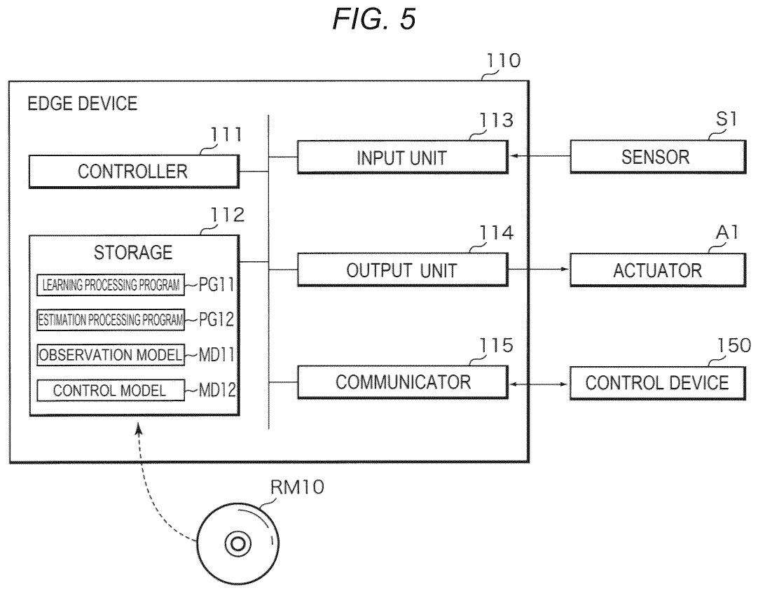

FIG. 5 is a block diagram illustrating an internal configuration of the edge device 110 provided in the substrate processing apparatus 100. The edge device 110 is a dedicated or general-purpose computer provided in the substrate processing apparatus 100, and includes a controller 111, a storage 112, an input unit 113, an output unit 114, a communicator 115, and the like. The edge device 110 monitors the state of the substrate processing apparatus 100 and controls the operation of the actuator A1 based on sensor data of the sensor S1 input through the input unit 113.

The controller 111 includes a central processing unit (CPU), a read only memory (ROM), a random access memory (RAM), and the like. The ROM provided in the controller 111 stores control programs and the like for controlling the operation of each component of the hardware provided in the edge device 110. The CPU in the controller 111 reads and executes control programs stored in the ROM and various types of computer programs stored in the storage 112, and controls the operation of each component of the hardware, and thus causes the entire apparatus to function as the information processing apparatus of the present disclosure. The RAM provided in the controller 111 temporarily stores data used during the execution of an arithmetic operation.

In the embodiment, although the controller 111 includes the CPU, the ROM, and the RAM, the configuration of the controller 111 is not limited to the above-described configuration. The controller 111 may be, for example, one or a plurality of control circuits or arithmetic circuits that include a graphic processing unit (GPU), a field programmable gate array (FPGA), a digital signal processor (DSP), a quantum processor, a volatile or nonvolatile memory, or the like. In addition, the controller 111 may include functions such as a clock for outputting date and time information, a timer for measuring the time elapsed from the time when a measurement start instruction is applied to the time when a measurement end instruction is applied, and a counter for counting the number.

The storage 112 includes storage devices such as a hard disk drive (HDD), a solid state drive (SSD), and an electronically erasable programmable read only memory (EEPROM). The storage 112 stores various types of computer programs executed by the controller 111 and various data used by the controller 111.

The computer programs stored in the storage 112 include a learning processing program PG11 for generating a learning model (the observation model MD11 and the control model MD12) to be described later, and an estimation processing program PG12 for estimating the state of the substrate processing apparatus 100 and the control value of the actuator A1 using the learning model. These computer programs may be single computer programs or may be configured to include a plurality of computer programs. In addition, these computer programs may partially use an existing library.

The computer programs such as the learning processing program PG11 and the estimation processing program PG12 stored in the storage 112 are provided by a non-temporary recording medium RM10 on which the computer programs are readable. The recording medium RM10 is a portable memory such as a CD-ROM, a USB memory, a secure digital (SD) card, a micro SD card, or a compact flash (registered trademark). The controller 111 reads various types of computer programs from the recording medium RM10 using a reading device (not illustrated) and stores the read various types of computer programs in the storage 112. The computer program stored in the storage 112 may be provided through communication. In this case, the controller 111 may acquire the computer program through the communicator 115, and store the acquired computer program in the storage 112.

The storage 112 includes a learning model configured to output information relating to the substrate processing apparatus 100 in a case where the time series data output from the sensor S1 is input. The storage 112 stores, as information defining the learning model, configuration information of layers provided in the learning model, information of the node included in each layer, weighting and bias parameters between nodes, and the like, for example.

The edge device 110 according to the present embodiment includes an observation model MD11 and a control model MD12 as learning models. The observation model MD11 is a model for estimating the state of the substrate processing apparatus 100. The control model MD12 is a model for estimating a control value of the actuator A1 which is a control target of the edge device 110. In the example illustrated in FIG. 5, although the learning model includes both the observation model MD11 and the control model MD12, only one of the observation model MD11 and the control model MD12 may be included. In addition, in the example illustrated in FIG. 5, although the observation model MD11 and the control model MD12 are provided one by one, the observation model MD11 may be prepared for each sensor that is an observation target, and the control model MD12 may be prepared for each actuator which is a control target.

The input unit 113 includes an interface for connecting the sensor S1. The sensor S1 connected to the input unit 113 is, for example, an RF sensor. The sensor S1 connected to the input unit 113 is not limited to the above-described sensor, and any sensor necessary for observing the state (performance) of the processing is connected thereto. The time series data (sensor data) input through the input unit 113 is temporarily stored in the storage 112.

The output unit 114 includes an interface for connecting the actuator A1 which is a control target of the edge device 110. The controller 111 estimates a control value using the control model MD12 described above, and controls the operation of the actuator A1 by outputting a control command based on the estimated control value from the output unit 114 to the actuator A1.

The communicator 115 includes a communication interface for transmitting and receiving various data to and from the control device 150. As the communication interface of the communicator 115, a communication interface conforming to a communication standard such as a LAN can be used. In a case where data to be transmitted is input from the controller 111, the communicator 115 transmits the data to the control device 150. In a case where the data transmitted from the control device 150 is received, the communicator 115 outputs the received data to the controller 111.

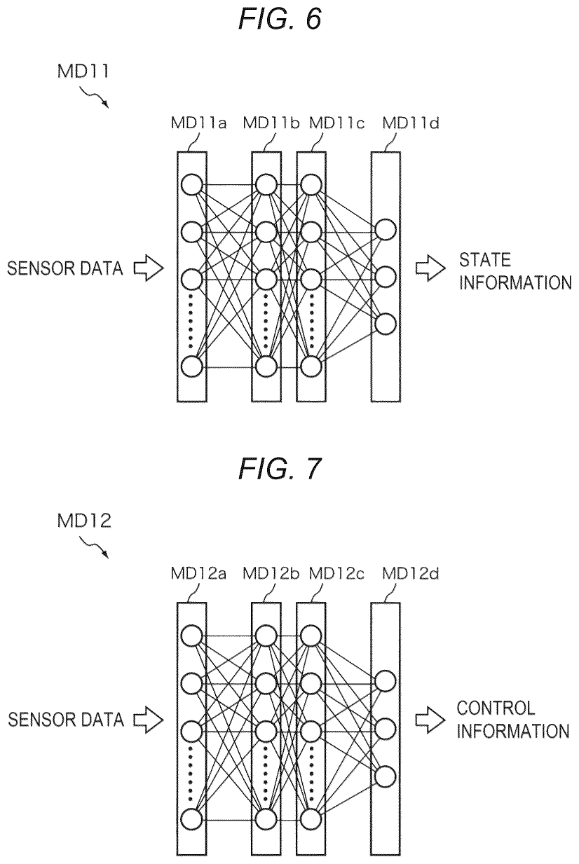

FIG. 6 is a schematic diagram illustrating a configuration example of the observation model MD11 provided in the edge device 110. The observation model MD11 is configured to output information relating to the state of the substrate processing apparatus 100 in which the sensor S1 is provided (hereinafter, referred to as state information) in a case where time series data (sensor data) obtained from the sensor S1 is input. As the observation model MD11, any model capable of analyzing time series data can be adopted. In an example, the observation model MD11 is a learning model of machine learning including deep learning, and is constructed to include Recurrent Neural Network (RNN), Long Short-Term Memory (LSTM), or the like. Alternatively, the observation model MD11 may be a learning model based on Convolutional Neural Network (CNN), Region-based CNN (R-CNN), You Only Look Once (YOLO), Single Shot Multibox Detector (SSD), Generative Adversarial Network (GAN), Support Vector Machine (SVM), a decision tree, or the like. Furthermore, the observation model MD11 may be a learning model other than deep learning, such as an autoregressive model, a moving average model, or an autoregressive moving average model.

The observation model MD11 includes an input layer MD11a, intermediate layers MD11b and MD11c, and an output layer MD11d. In the example of FIG. 6, although the observation model MD11 includes the two intermediate layers MD11b and MD11c, the observation model MD11 may include three or more intermediate layers.

One or a plurality of nodes are provided in the input layer MD11a, the intermediate layers MD11b, MD11c, and the output layer MD11d. The node of each layer is joined to the node existing in the preceding and subsequent layers with the desired weight and bias in one direction. The same number of data as the number of nodes included in the input layer MD11a is input to the input layer MD11a of the observation model MD11. In the present embodiment, the sensor data input to the node of the input layer MD11a is time series data obtained from the sensor S1. The sensor data input to the input layer MD11a may be a plurality of measured values continuous in time, or may be a graph (image data) in which measured values are plotted against time.

The input sensor data is output to the node provided in the first intermediate layer MD11b through the node provided in the input layer MD11a. The data input to the first intermediate layer MD11b is output to the node provided in the second intermediate layer MD11c through the node constituting the intermediate layer MD11b. During this time, feature values of the sensor data are extracted using the activation functions that include the weights and biases set between the nodes of each of the layers.

The feature values of the sensor data extracted by the intermediate layers MD11b and MD c are output to the output layer MD11d and extracted outside the observation model MD11. The output layer MD11d executes an arithmetic operation set in advance using the feature value input from the second intermediate layer MD11c, and outputs state information of the substrate processing apparatus 100 as a final arithmetic result.

The state information output from the output layer MD11d includes an evaluation value or the like representing the state of the substrate processing apparatus 100. The evaluation value is, for example, information indicating the degree of deterioration of a specific component constituting the substrate processing apparatus 100. Alternatively, the evaluation value may be information indicating the presence or absence of a failure of a specific component. The specific components constituting the substrate processing apparatus 100 include the exhaust device 51, the heater power supply 64, the gas source 73, the radio-frequency power supply 76, and the like.

The observation model MD11 is learned by any learning algorithm. As the learning algorithm, learning with a teacher can be used. In this case, in a case where a data set that includes sensor data of the sensor S1 and ground truth data to be output by the observation model MD11 is used as training data and sensor data is input, it is learned to output state information of the substrate processing apparatus 100. The training data may be provided by an administrator of the substrate processing apparatus 100 or the like. For example, the sensor data of the sensor S1, the date and time when the component is replaced, the date and time when a failure is detected, and the like are stored as history data. Based on this history data, the sensor data of the sensor S1 and the ground truth data indicating the presence or absence of deterioration or failure at the date and time when the sensor data is obtained may be provided as training data.

The observation model MD11 illustrated as an example in FIG. 6 is configured to include the input layer MD11a, the intermediate layers MD11b, MD11c, and the output layer MD11d. However, the configuration of the observation model MD11 is not limited to that illustrated in FIG. 6. For example, the observation model MD11 may be a model in which only the relationship between input and output (that is, the relationship between sensor data and state information) is defined without including the intermediate layers MD11b and MD11c.

In the present embodiment, although learning with a teacher is described as the learning algorithm of the observation model MD11, the observation model MD11 can be generated using any learning algorithm including learning without a teacher.

In a case where an arithmetic operation is executed by the observation model MD11, the controller 111 of the edge device 110 acquires state information from the output layer MD11d and acquires the feature values of sensor data extracted by the intermediate layers MD11b and MD11c. The controller 111 transmits the acquired state information on the substrate processing apparatus 100 and the feature value of the sensor data to the control device 150, which is a host device of the edge device 110.

FIG. 7 is a schematic diagram illustrating a configuration example of the control model MD12 provided in the edge device 110. The control model MD12 is configured to output information relating to a control value (hereinafter referred to as control information) of the substrate processing apparatus 100 in which the sensor S1 is provided, in a case where time series data (sensor data) obtained from the sensor S1 is input. That is, in a case where sensor data is input to an input layer MD12a of the control model MD12, an arithmetic operation for extracting the feature value of sensor data is executed in intermediate layers MD12b and MD12c. The feature values obtained from the intermediate layers MD12b and MD12c are output to an output layer MD12d and extracted outside the control model MD12. The output layer MD12d executes a predetermined arithmetic operation using the feature value input from the second intermediate layer MD12c, and outputs control information of the substrate processing apparatus 100 as a final arithmetic result. The feature value of the sensor data output from the intermediate layer MD12c and the control information output from the output layer MD12d are input to the controller 111. The control information output from the output layer MD12d includes the control value for controlling at least one component provided in the substrate processing apparatus 100.

Similar to the observation model MD11, the control model MD12 may be learned through learning with a teacher or may be learned through learning without a teacher. In addition, the control model MD12 may be learned through reinforcement learning. For example, a reward may be given according to the state of the substrate processing apparatus 100, and the value in the reinforcement learning may be learned so as to maximize the total of the rewards obtained in the future. For example, in Q learning, which is one type of reinforcement learning, a value Q for selecting an action (control value) is learned under conditions in a certain environment. At the time of starting the Q learning, a correct value of the value Q is not known with respect to the combination of the state and the action (control value) of the substrate processing apparatus 100. Therefore, various control values are selected under certain work data, the total of the rewards is calculated based on the rewards given to the actions at that time (controls based on control values), and the correct value Q is learned by selecting better control values.

The control model MD12 is not limited to the above-described model, and may be another model capable of analyzing time series data. For example, the control model MD12 may be a learning model other than deep learning, such as an autoregressive model, a moving average model, or an autoregressive moving average model. In addition, the configuration of the control model MD12 is not limited to that illustrated in FIG. 7. For example, the control model MD12 may be a model in which only the relationship between input and output (that is, the relationship between sensor data and control information) is defined without including the intermediate layers MD12b and MD12c.

In a case where an arithmetic operation is executed by the control model MD12, the controller 111 of the edge device 110 acquires control information from the output layer MD12d and acquires feature values of sensor data calculated by the intermediate layers MD12b and MD12c. The controller 111 transmits the acquired control information on the substrate processing apparatus 100 and the feature value of the sensor data to the control device 150, which is the host device of the edge device 110. In addition, the controller 111 controls the operation of the actuator A1 based on the control information acquired from the control model MD12.

In the present embodiment, although the feature values are extracted from the intermediate layers MD11c and MD12c, the final arithmetic results obtained from the output layers MD11d and MD12d may be regarded as the feature values of the sensor data. In addition, the controller 111 may extract the feature value directly from the sensor data. Appropriate statistical processing such as peak detection and interval averaging is used for the extraction of the feature values. The controller 111 may detect an abnormal location appearing in the sensor data, and extract a feature value by weighting the data of the detected abnormal location. In addition, the controller 111 may extract a snapshot of the time series data that includes the abnormal location appearing in the sensor data as a feature value.

In FIGS. 5 to 7, although the internal configuration of the edge device 110 is described, the same applies to the internal configurations of the edge devices 120 and 130. That is, each of the edge devices 120 and 130 includes the observation model and the control model, and estimates the states of the substrate processing apparatus 100 and the control values of the actuators A1 and A2 based on the sensor data input from the sensors S2 and S3. The edge devices 120 and 130 transmit state information on the substrate processing apparatus 100 obtained from the observation model and the control model, control information on the actuators A1 and A2, and feature values of sensor data output from the sensors S2 and S3 to the control device 150, which is a host device of the edge devices 120 and 130. In addition, each of the edge devices 120 and 130 controls the operations of the actuators A2 and A3 based on the control information acquired from the control model.

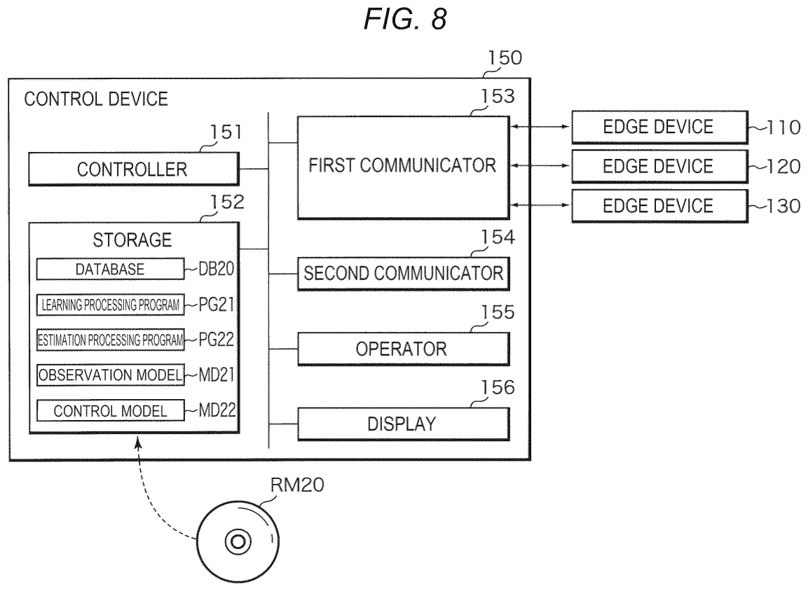

FIG. 8 is a block diagram illustrating an internal configuration of the control device 150 provided in the substrate processing apparatus 100. The control device 150 is a dedicated or general-purpose computer provided inside the substrate processing apparatus 100, and includes a controller 151, a storage 152, a first communicator 153, a second communicator 154, an operator 155, and a display 156. The control device 150 collects data (feature value of sensor data) transmitted from the edge devices 110 to 130, and stores the data in a database DB20 in the storage 152. The control device 150 generates a second learning model that absorbs individual differences between sensors based on the medium-term data stored in the database DB20.

The controller 151 includes a CPU, a ROM, a RAM, and the like. The ROM provided in the controller 151 stores control programs and the like for controlling the operation of each component of the hardware provided in the control device 150. The CPU in the controller 151 reads and executes control programs stored in the ROM and various types of computer programs stored in the storage 152, and controls the operation of each component of the hardware.

The controller 151 is not limited to the configuration described above, and may be one or a plurality of control circuits or arithmetic circuits that include a GPU, an FPGA, a DSP, a quantum processor, a volatile or nonvolatile memory, or the like. In addition, the controller 151 may include functions such as a clock for outputting date and time information, a timer for measuring the time elapsed from the time when a measurement start instruction is applied to the time when a measurement end instruction is applied, and a counter for counting the number.

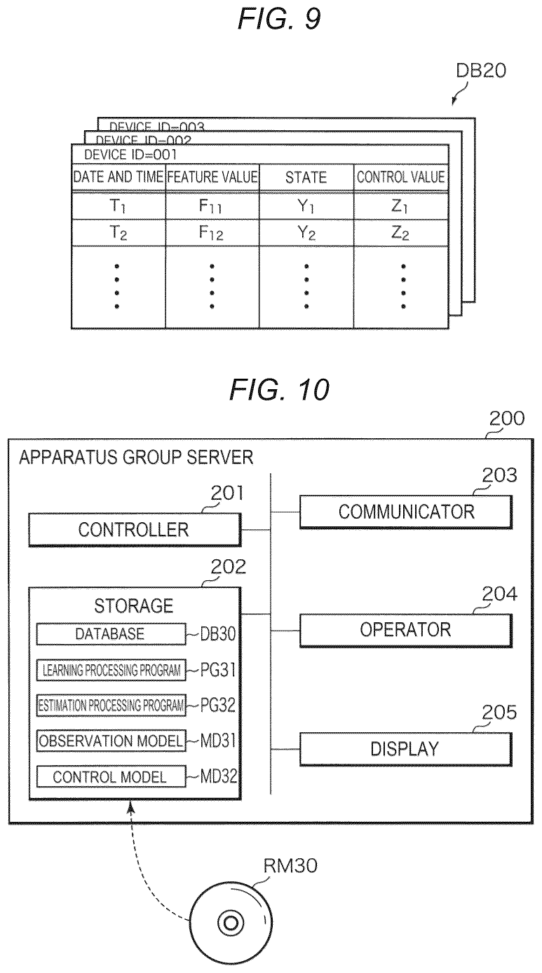

The storage 152 includes storage devices such as an HDD, an SSD, and an EEPROM. The storage 152 includes the database DB20 described above. FIG. 9 is a conceptual diagram illustrating a configuration example of the database DB20. The database DB20 stores date and time information and the feature value of sensor data in association with the identification information (device IDs) of the edge devices 110 to 130. Furthermore, the database DB20 may store state information and control information of the substrate processing apparatus 100.

In addition to the database DB20, the storage 152 stores various types of computer programs executed by the controller 151, and various data used by the controller 151.

The computer programs stored in the storage 152 include a learning processing program PG21 for generating a second learning model, and an estimation processing program PG22 for estimating the state and the control value of the substrate processing apparatus 100 using the second learning model. The computer program stored in the storage 152 is provided by a non-temporary recording medium RM20 on which the computer program is readable. In addition, the computer program stored in the storage 152 may be provided through communication.

The storage 152 includes a second learning model configured to output information relating to the substrate processing apparatus 100 in a case where the feature value of the sensor data is input. The storage 152 stores, as information defining the second learning model, configuration information of layers provided in the second learning model, information of nodes included in each layer, weighting and bias information between nodes, and the like.

The control device 150 includes an observation model MD21 and a control model MD22 as the second learning model. The observation model MD21 is a model for estimating the state of the substrate processing apparatus 100. The control model MD22 is a model for estimating a control value used in the substrate processing apparatus 100. Since the configurations of the observation model MD21 and the control model MD22 are the same as the configurations of the observation model MD11 and the control model MD12 provided in the edge devices 110 to 130, detailed descriptions thereof will be omitted.

In the present embodiment, although the second learning model includes both the observation model MD21 and the control model MD22, only one of the observation model MD21 and the control model MD22 may be included. In addition, in the present embodiment, although the observation model MD21 and the control model MD22 are provided one by one as the second learning model, the observation model MD21 may be prepared for each observation target, and the control model MD22 may be prepared for each control target.

The first communicator 153 includes a communication interface for transmitting and receiving various data to and from the edge devices 110 to 130. As the communication interface of the first communicator 153, a communication interface conforming to a communication standard such as a LAN can be used. The first communicator 153 transmits data to destination edge devices 110 to 130 in a case where data to be transmitted is input from the controller 151, and outputs the received data to the controller 151 in a case where data transmitted from the edge devices 110 to 130 is received.

The second communicator 154 includes a communication interface for transmitting and receiving various data. The communication interface provided in the second communicator 154 is, for example, a communication interface conforming to the communication standard of a LAN used in WiFi (registered trademark) or Ethernet (registered trademark). In a case where data to be transmitted is input from the controller 151, the second communicator 154 transmits data to be transmitted to the designated destination. In addition, in a case where the data transmitted from an external device is received, the second communicator 154 outputs the received data to the controller 151.

The operator 155 includes operating devices such as a touch panel, a keyboard, and switches, and receives various types of operations and settings by an administrator or the like. The controller 151 performs appropriate controls based on various operation information supplied by the operator 155, and causes the storage 152 to store setting information as necessary.

The display 156 includes a display device such as a liquid crystal monitor or an organic electro-luminescence (EL), and displays information to be notified to an administrator or the like in response to an instruction from the controller 151.

Next, the configuration of the apparatus group server 200 will be described. FIG. 10 is a block diagram illustrating an internal configuration of the apparatus group server 200. The apparatus group server 200 includes a controller 201, a storage 202, a communicator 203, an operator 204, and a display 205. The apparatus group server 200 collects data transmitted from the plurality of substrate processing apparatuses 100, and stores the data in the database DB30 provided in the storage 202. The apparatus group server 200 generates a third learning model that absorbs individual differences between the apparatuses based on the long-term data stored in a database DB30.

The controller 201 includes a CPU, a ROM, a RAM, and the like. The ROM provided in the controller 201 stores control programs and the like for controlling the operation of each component of the hardware provided in the apparatus group server 200. The CPU in the controller 201 reads and executes control programs stored in the ROM and various types of computer programs stored in the storage 202, and controls the operation of each component of the hardware.

The controller 201 is not limited to the configuration described above, and may be one or a plurality of control circuits or arithmetic circuits that include a GPU, an FPGA, a DSP, a quantum processor, a volatile or nonvolatile memory, or the like. In addition, the controller 201 may include functions such as a clock for outputting date and time information, a timer for measuring the time elapsed from the time when a measurement start instruction is applied to the time when a measurement end instruction is applied, and a counter for counting the number.

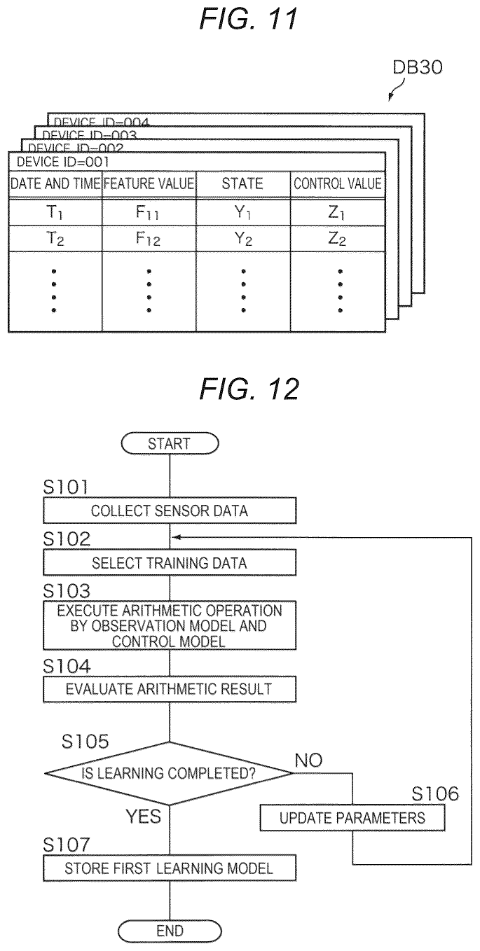

The storage 202 includes storage devices such as an HDD, an SSD, and an EEPROM. The storage 202 includes the database DB30 described above. FIG. 11 is a conceptual diagram illustrating a configuration example of the database DB30. The database DB30 stores date and time information and the feature value of sensor data in association with the identifier (apparatus ID) of the substrate processing apparatus 100. The database DB30 may further store state information indicating the state of the substrate processing apparatus 100 and control information used for controlling the substrate processing apparatus 100.

In addition to the database DB30, the storage 202 stores various types of computer programs executed by the controller 201 and various data used by the controller 201.

The computer programs stored in the storage 202 include a learning processing program PG31 for generating a third learning model, and an estimation processing program PG32 for estimating the state and the control value of the substrate processing apparatus 100. The computer program stored in the storage 202 is provided by a non-temporary recording medium RM30 on which the computer program is readable. In addition, the computer program stored in the storage 202 may be provided through communication.

The storage 202 includes a third learning model configured to output information relating to the substrate processing apparatus 100 in a case where the feature value of the sensor data is input. The storage 202 stores, as information defining the third learning model, configuration information of layers provided in the third learning model, information of the node included in each layer, weighting and bias information between nodes, and the like.

The apparatus group server 200 includes an observation model MD31 and a control model MD32 as the third learning model. The observation model MD31 is a model for estimating the state of the substrate processing apparatus 100. The control model MD32 is a model for estimating a control value used in the substrate processing apparatus 100. Since the configurations of the observation model MD31 and the control model MD32 are the same as the configurations of the observation model MD21 and the control model MD22 provided in the control device 150, detailed descriptions thereof will be omitted.

In the present embodiment, although the third learning model includes both the observation model MD31 and the control model MD32, only one of the observation model MD31 and the control model MD32 may be included. In addition, in the present embodiment, although the observation model MD31 and the control model MD32 are provided one by one as the third learning model, the observation model MD31 may be prepared for each observation target, and the control model MD32 may be prepared for each control target.

The communicator 203 includes a communication interface for transmitting and receiving various data. The communication interface provided in the communicator 203 is, for example, a communication interface conforming to a communication standard of a LAN used in WiFi (registered trademark) or Ethernet (registered trademark). In a case where data to be transmitted is input from the controller 201, the communicator 203 transmits data to be transmitted to the designated destination. In addition, in a case where data transmitted from an external device is received, the communicator 203 outputs the received data to the controller 201.

The operator 204 includes operating devices such as a touch panel, a keyboard, and switches, and receives various types of operations and settings by an administrator or the like. The controller 201 performs appropriate controls based on various operation information supplied by the operator 204, and causes the storage 202 to store setting information as necessary.

The display 205 includes a display device such as a liquid crystal monitor or an organic EL, and displays information to be notified to an administrator or the like in response to an instruction from the controller 201.

In the example of FIG. 10, although the apparatus group server 200 includes the operator 204 and the display 205, the operator 204 and the display 205 are not essential elements in the apparatus group server 200. In a case where the operator 204 is not provided, the apparatus group server 200 may receive an operation from an external computer communicably connected through the communicator 203. In addition, in a case where the display 205 is not provided, the apparatus group server 200 may transmit information to be notified to an administrator or the like from the communicator 203 to the external computer, and display the information on the external computer.

Hereinafter, the operation of the substrate processing system will be described.

In the substrate processing system according to the present embodiment, the edge devices 110 to 130 generate the first learning model (the observation model MD11 and the control model MD12) in the learning phase before the start of the operation.

FIG. 12 is a flowchart illustrating a procedure for generating the first learning model by the edge device 110. The controller 111 of the edge device 110 collects sensor data that is output from the sensor S1 in time series through the input unit 113 (step S101). The sensor data collection period is, for example, one month. When acquiring the sensor data, the controller 111 receives state information of the substrate processing apparatus 100 from the outside, and acquires a control value to be output from the output unit 114 to the substrate processing apparatus 100. The control value of the substrate processing apparatus 100 used at a stage where the learning of the control model MD12 is not completed is determined with reference to, for example, a recipe set in advance. These state information and the control value are stored in the storage 112 as training data at the time of learning the observation model MD11 and the control model MD12, together with the sensor data.

In a case where the training data necessary for the learning is obtained, the controller 111 selects a set of training data from the training data stored in the storage 112 (step S102). The controller 111 inputs sensor data included in the selected set of training data into each of the observation model MD11 and the control model MD12, and executes an arithmetic operation of the observation model MD11 and the control model MD12 (step S103). It is assumed that an initial value is set for the model parameters of the observation model MD11 and the control model MD12 at a stage before the start of the learning.

The controller 111 evaluates the arithmetic results of the observation model MD11 and the control model MD12 (step S104), and determines whether the learning of the observation model MD11 and the control model MD12 is completed (step S105). The controller 111 can evaluate the arithmetic result using an error function (also referred to as an objective function, a loss function, or a cost function) based on the arithmetic result by the model and a state or control value included as the ground truth data. For example, the controller 111 determines that the learning of the observation model MD11 and the control model MD12 is completed, in a case where the error function becomes a threshold value or lower (or a threshold value or higher) in the process of optimizing (minimizing or maximizing) the error function by a gradient descent method such as a steepest descent method.

In a case where the learning is not completed (NO in step S105), that is, in a case where the learning of either the observation model MD11 or the control model MD12 is not completed, the controller 111 updates the parameters (such as the weights and biases between the nodes) of the model for which the learning is not completed (step S106), and returns the processing to step S102. The controller 111 can update the parameters in the model using an error back propagation method that successively updates the weights and biases between the nodes from the output layers MD11d and MD12d toward the input layers MD11a and MD12a.

In a case where it is determined that the learning is completed (step S105: YES), since the learned observation model MD11 and control model MD12 are obtained, the controller 111 causes the storage 112 to store these models as the first learning model (step S107).

In FIG. 12, although the procedure for generating the first learning model by the edge device 110 is described, even in the edge devices 120 and 130, the first learning model to be applied to each of the edge devices 120 and 130 can be generated through the same generation procedure.

The substrate processing system of the present embodiment shifts to an operational phase after the first learning model is generated in each of the edge devices 110 to 130. The substrate processing system executes the following processing in the operational phase.

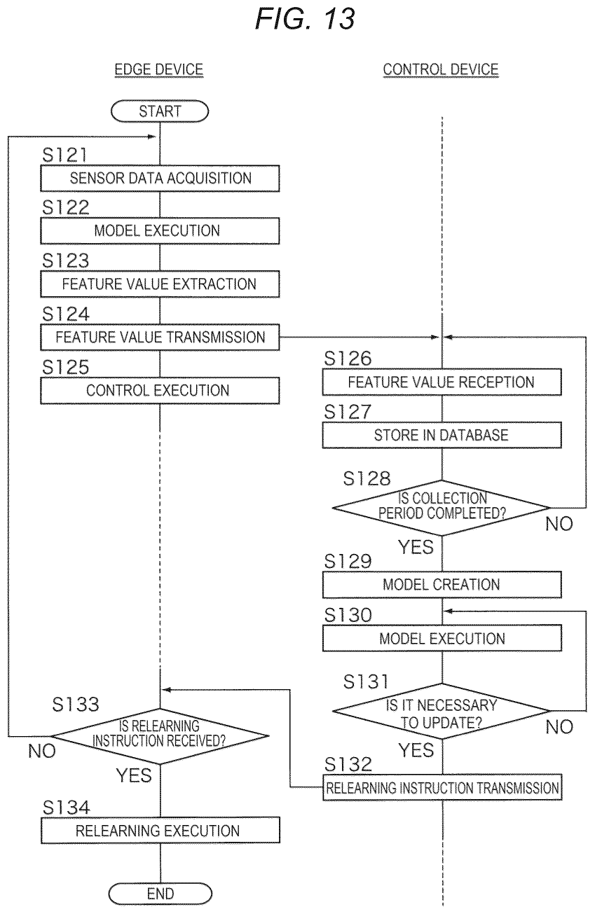

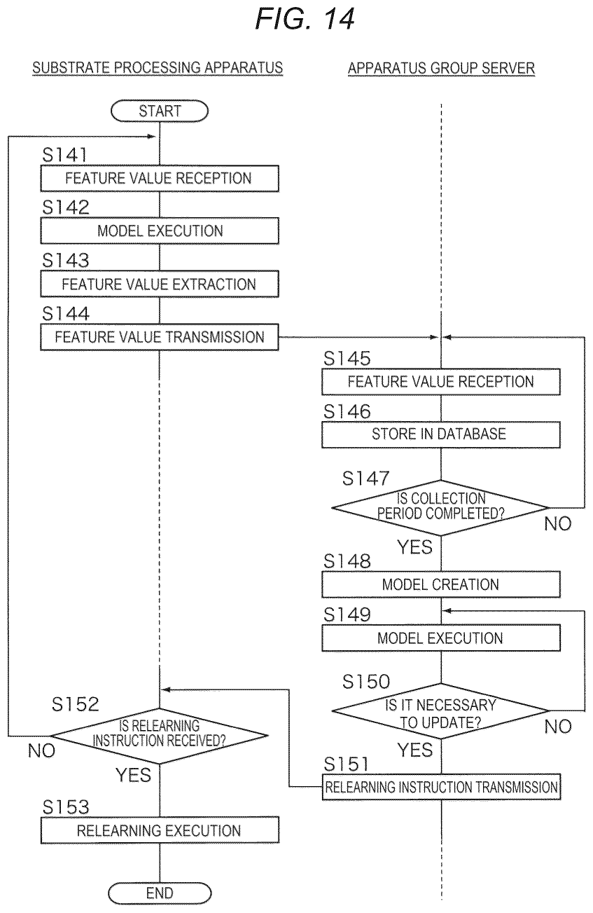

FIG. 13 is a flowchart illustrating a procedure of processing executed in the substrate processing apparatus 100 in the operational phase. In a case where sensor data output from the sensor S1 in time series through the input unit 113 is acquired (step S121), the controller 111 of the edge device 110 (120, 130) provided in the substrate processing apparatus 100 executes the model by inputting the acquired sensor data to the observation model MD11 or the control model MD12 (step S122).

In the process of executing the model, the controller 111 extracts feature values of sensor data from the intermediate layers MD11c and MD12c of each of the models MD11 and MD12 (step S123). The controller 111 can extract feature values from the intermediate layers MD11c and MD12c, for example. Alternatively, the controller 111 may regard the final arithmetic results obtained from the output layers MD11d and MD12d as feature values of sensor data, or may directly extract the feature values from the sensor data.

The controller 111 transmits the extracted feature values, together with the estimation results of the state information and control information obtained from each of the models MD11 and MD12, to the control device 150 (step S124). In addition, the controller 111 also executes control of the actuator A1 based on the state information and control information estimated by each of the models MD11 and MD12 (step S125). The controller 111 may execute the processing of steps S122 to S125 each time sensor data is acquired in step S122.

The controller 151 of the control device 150 receives the feature value transmitted from the edge device 110 (120, 130) from the first communicator 153 (step S126) and stores the feature value in the database DB20 (step S127).

In step S128, the controller 151 determines whether or not the collection period for the feature value is completed. The collection period is, for example, 6 months from the start of the collection of the feature values. Alternatively, it may be determined whether or not the collection period is completed based on the number of feature values stored in the database DB20. In a case where the collection period is not completed (NO in step S128), the controller 151 returns the processing to step S126, and repeats the processing of receiving the feature value and storing the feature value in the database DB20.

In a case where the collection period is completed (step S128: YES), the learning of the observation model MD21 and the control model MD22 is executed to create a model (step S129). For example, the controller 151 can create the observation model MD21 by performing learning using a set of feature values and state information stored in the database DB20 as training data. In addition, the controller 151 can create the control model MD22 by performing learning using a set of the feature value and the control value stored in the database DB20 as training data. The procedure for creating the model is the same as the procedure for creating the observation model MD11 and the control model MD12.

In a case where a new feature value from the edge device 110 (120, 130) is received after the model is created, the controller 151 inputs the received feature value into the observation model MD21 or the control model MD22, and executes the model (step S130).

The controller 151 determines whether or not it is necessary to update the model used in the edge device 110 (120, 130) based on the execution result of step S130 (step S131). Since the control device 150 creates the model based on the medium-term data (for example, data in units of six months) stored, the controller 151 can determine the deviation from the trend indicated by the model by executing the model based on the newly acquired feature values. In a case where the deviation from the trend indicated by the model is the threshold value or larger, the controller 151 determines that the model provided in the edge device 110 (120, 130) has an abnormality. In a case where it is determined that the model does not have any abnormality, the controller 151 determines that it is not necessary to update the model (NO in step S131), and the controller 151 returns the processing to step S130.

In a case where it is determined that the model has an abnormality, the controller 151 determines that it is necessary to update the model (step S131: YES), and transmits a relearning instruction of the model to the edge device 110 (120, 130) (step S132).

The controller 111 of the edge device 110 (120, 130) determines whether or not a relearning instruction transmitted from the control device 150 is received (step S133). In a case where it is determined that the relearning instruction is not received (NO in step S133), the controller 111 returns the processing to step S121, and repeatedly executes the processing in steps S121 to 5125.

In a case where the relearning instruction is received (step S133: YES), the controller 111 executes relearning (step S134). For example, the controller 111 can relearn the observation model MD11 by performing additional learning using the sensor data obtained from the sensor S1 and the state information of the substrate processing apparatus 100 using as training data. In addition, for example, the controller 111 can relearn the control model MD12 by performing additional learning using the sensor data obtained from the sensor S1 and the control value used in the substrate processing apparatus 100 using as training data. Instead of the configuration in which the observation model MD11 and the control model MD12 are relearned through additional learning, the observation model MD11 and the control model MD12 may be relearned from the beginning using the training data.

In the present flowchart, in a case where it is determined that it is necessary to update the model in the control device 150, although a relearning instruction is transmitted to the edge device 110 (120, 130), a correction value for correcting the arithmetic result of each of the models MD11, MD12 may be transmitted to the edge device 110 (120, 130). For example, the correction value can be calculated from the error between the prediction result and the actual measurement result obtained by the second learning model (the observation model MD21 and the control model MD22).

FIG. 14 is a flowchart illustrating a procedure of processing executed between the substrate processing apparatus 100 and the apparatus group server 200 in the operational phase. As described above, in the operational phase, the control device 150 of the substrate processing apparatus 100 creates the observation model MD21 and the control model MD22 based on the feature values obtained from the edge devices 110 to 130. In a case where a new feature value from the edge device 110 (120, 130) is received after the model is created (step S141), the controller 151 of the control device 150 inputs the received feature value into the observation model MD21 or the control model MD22, and executes the model (step S142).

In the process of executing the model, the controller 111 extracts a feature value of sensor data from the intermediate layer of each of the models MD21 and MD22 (step S143), and transmits the extracted feature values, together with the estimation results of the state information and control information obtained from each of the models MD21 and MD22, to the apparatus group server 200 (step S144). In the present embodiment, the feature value of the sensor data is extracted from the intermediate layer of each of the models MD21 and MD22 and transmitted to the apparatus group server 200. However, the final arithmetic results obtained from the output layer of each of the models MD21 and MD22 may be regarded as the feature value of the sensor data and transmitted to the apparatus group server 200.

The controller 201 of the apparatus group server 200 receives the feature value transmitted from the substrate processing apparatus 100 from the communicator 203 (step S145) and stores the feature value in the database DB30 (step S146).

In step S147, the controller 201 determines whether or not the collection period for the feature value is completed (step S147). The collection period is, for example, two to three years from the start of the collection of the feature values. Alternatively, it may be determined whether or not the collection period is completed based on the number of feature values stored in the database DB30. In a case where the collection period is not completed (NO in step S147), the controller 201 returns the processing to step S145, and repeats the processing of receiving the feature value and storing the feature value in the database DB30.

In a case where the collection period is completed (step S147: YES), the learning of the observation model MD31 and the control model MD32 is executed to create a model (step S148). For example, the controller 201 can create the observation model MD31 by performing learning using a set of feature values and state information stored in the database DB30 as training data. In addition, the controller 201 can create the control model MD32 by performing learning using a set of feature values and control values stored in the database DB30 as training data. The procedure for creating the model is the same as the procedure for creating the observation model MD11 and the control model MD12.

In a case where a new feature value from the substrate processing apparatus 100 is received after the model is created, the controller 201 inputs the received feature value into the observation model MD31 or the control model MD32, and executes the model (step S149).

The controller 201 determines whether or not it is necessary to update the model used in the edge device 110 (120, 130) of the substrate processing apparatus 100 based on the execution result of step S149 (step S150). Since the apparatus group server 200 creates the model based on the stored long-term data (for example, data in units of two to three years), the controller 201 can determine the deviation from the trend indicated by the model by executing the model based on the newly acquired feature values. In a case where the deviation from the trend indicated by the model is the threshold value or larger, the controller 201 determines that the model of the edge device 110 (120, 130) has an abnormality. In a case where it is determined that the model does not have any abnormality, the controller 201 determines that it is not necessary to update the model (NO in step S150), and the controller 201 returns the processing to step S149.

In a case where it is determined that the model has an abnormality, the controller 201 determines that it is necessary to update the model (step S150: YES), and transmits a relearning instruction of the model to the substrate processing apparatus 100 (step S151).

The controller 151 of the control device 150 provided in the substrate processing apparatus 100 determines whether or not a relearning instruction transmitted from the apparatus group server 200 is received (step S152). In a case where it is determined that the relearning instruction is not received (NO in step S152), the controller 151 returns the processing to step S141, and repeatedly executes the processing in steps S141 to 5144.

In a case where the relearning instruction is received (step S152: YES), the controller 151 applies an instruction to the edge device 110 (120, 130) to execute the relearning (step S153). For example, the controller 111 of the edge device 110 (120, 130) can relearn the observation model MD11 by performing additional learning using the sensor data obtained from the sensor S1 and the state information of the substrate processing apparatus 100 using as training data. In addition, for example, the controller 111 can relearn the control model MD12 by performing additional learning using the sensor data obtained from the sensor S1 and the control value used in the substrate processing apparatus 100 using as training data. Instead of the configuration in which the observation model MD11 and the control model MD12 are relearned through additional learning, the observation model MD11 and the control model MD12 may be relearned from the beginning using the training data.

In the flowchart, the observation model MD11 and the control model MD12 are retrained in the edge device 110 (120, 130) in a case where a relearning instruction is applied from the apparatus group server 200. However, the observation model MD21 and the control model MD22 may be relearned in the control device 150. The controller 151 of the control device 150 can relearn the observation model MD21 using the feature value and the state information stored in the database DB20 using as training data. In addition, the controller 151 can relearn the control model MD22 using the feature value and control value stored in the database DB20 using as training data. The controller 151 may relearn the observation model MD21 and the control model MD22 through the additional learning, or may relearn the observation model MD21 and the control model MD22 from the beginning using the training data.

In the present flowchart, in a case where it is determined that it is necessary to update the model in the apparatus group server 200, although a relearning instruction is transmitted to the substrate processing apparatus 100, a correction value for correcting the arithmetic result of the model may be transmitted to the substrate processing apparatus 100. For example, the correction value can be calculated from the error between the prediction result and the actual measurement result obtained by the third learning model (the observation model MD31 and the control model MD32).

As described above, in the present embodiment, each of the edge devices 110 to 130 can create a high-definition model (the observation model MD11 and the control model MD12) based on sensor data. In addition, the edge devices 110 to 130 may create a model for estimating the deterioration of components provided in the substrate processing apparatus 100 based on the acquired sensor data.

Since each of the edge devices 110 to 130 transmits the feature value extracted by each model to the control device 150 without transmitting the sensor data, the network load between the edge devices 110 to 130 and the control device 150 can be reduced. The control device 150 can create models of medium-term trends (the observation model MD21 and the control model MD22) based on the feature value of the sensor data.

Since each of the substrate processing apparatuses 100 transmits the feature value extracted by each model to the apparatus group server 200, the network load between the substrate processing apparatus 100 and the apparatus group server 200 can be reduced. The apparatus group server 200 can create long-term trend models (the observation model MD31 and the control model MD32) that absorb individual differences between the apparatuses based on the feature value transmitted from the substrate processing apparatus 100.

In a case where a new substrate processing apparatus (not illustrated) is installed in the substrate processing system, the learned first learning model (the observation model MD11 and the control model MD12) may be deployed to each of the edge devices 110 to 130. Furthermore, the learned second learning model (the observation model MD21 and the control model MD22) may be deployed to the control device 150 of each substrate processing apparatus 100.

### Embodiment 2

In Embodiment 2, a configuration will be described in which the completeness and soundness of the first learning model are evaluated and the evaluation results are output.

The system configuration, the internal configurations of the substrate processing apparatus 100, and the apparatus group server 200 are the same as those in Embodiment 1, and thus descriptions thereof will be omitted.

The substrate processing apparatus 100 evaluates the completeness and soundness of the first learning model (the observation model MD11 and the control model MD12) provided in the edge devices 110 to 130 at the appropriate timing of the learning phase or the operational phase, and outputs the evaluation results.

In the substrate processing apparatus 100, a data set for evaluation is prepared in order to evaluate the first learning model (the observation model MD11 and the control model MD12). For example, in order to evaluate the observation model MD11 provided in the edge device 110, a set that includes the sensor data of the sensor S1 and the ground truth data to be output by the observation model MD11 in a case where the sensor data of the sensor S1 is input may be used as a data set for evaluation. Similarly, in order to evaluate the control model MD12 provided in the edge device 110, a set that includes the sensor data of the sensor Si and the ground truth data to be output by the control model MD12 in a case where the sensor data of the sensor S1 is input may be used as a data set for evaluation. The same applies to the data set for evaluation for evaluating the edge devices 120 and 130.

The substrate processing apparatus 100 can evaluate the completeness and soundness of the first learning model based on differences between the estimated value obtained in a case where sensor data included in the data set for evaluation are input into the observation model MD11 and the control model MD12 and the ground truth data included in the data set.

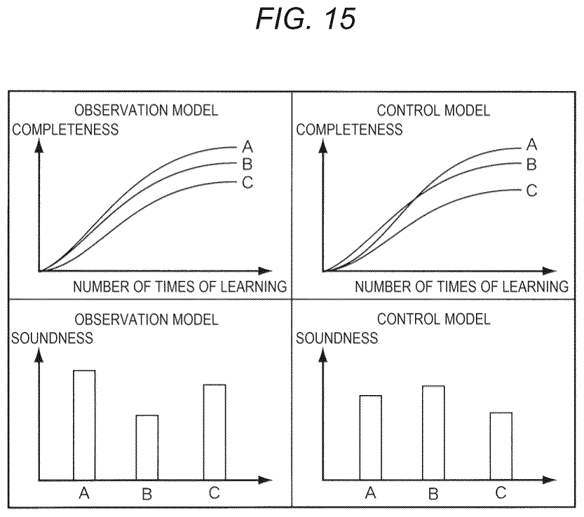

In a case where the completeness and soundness of the first learning model are evaluated, the substrate processing apparatus 100 displays the evaluation results on the display 156. FIG. 15 is a schematic diagram illustrating a display example of evaluation results. The example of FIG. 15 illustrates the results of evaluating the completeness and soundness of the observation model MD11 and the control model MD12 provided in each of the edge devices 110 to 130. In each graph, each of indices A, B, and C represents the edge devices 110, 120, and 130. The upper graph illustrates the fact that the completeness of the observation model MD11 and the control model MD12 increases with the increase in the number of times of learning. The lower graph illustrates the soundness of the observation model MD11 and the control model MD12 provided in each of the edge devices 110, 120, and 130 at the time of evaluation.

In this manner, in Embodiment 2, since the performance of each learning model can be displayed in a list, in a case where the completeness and soundness of the observation model MD11 and the control model MD12 are insufficient, the administrator can improve the completeness and soundness of the observation model MD11 and the control model MD12 by applying a relearning instruction through the operator 155.

The embodiments disclosed herein are exemplary in all respects and are required to be considered to be not restrictive embodiments. The scope of the present invention is indicated by the scope of the claims, not the meaning described above, and is intended to include meanings equivalent to the scope of the claims and all changes within the scope.

1. An information processing method comprising:
acquiring time series data from a plurality of types of sensors having different sampling periods provided in a substrate processing apparatus;
performing learning of first learning models that output information relating to the substrate processing apparatus in a case where the time series data from the sensors are input, using each of the pieces of time series data having different sampling periods for each of the sensors individually; and
inputting the time series data from the sensors into the corresponding first learning models after learning to output an estimation result based on information obtained from the first learning models.

2. The information processing method according to claim 1, wherein
the first learning model of each of the sensors is introduced for each of the edge devices corresponding to each of the sensors, and
the method further comprises
executing learning processing of the first learning model and estimation processing by the first learning model in each of the edge devices.

3. The information processing method according to claim 1, wherein
the first learning models include at least one of
an observation model for estimating a state of the substrate processing apparatus based on the time series data from the sensor, and
a control model for estimating a control value of the substrate processing apparatus based on the time series data from the sensor.

4. The information processing method according to claim 1, further comprising:
extracting a first feature value from the time series data; and
outputting the extracted first feature value to a first device in the substrate processing apparatus.

5. The information processing method according to claim 4, further comprising:
executing, in the first device,
processing of storing the first feature value extracted from the time series data,
processing of performing learning of a second learning model that outputs the information relating to the substrate processing apparatus in a case where the first feature value is input based on the stored first feature value, and
processing of inputting a newly acquired first feature value into a second learning model after learning to output an estimation result based on information obtained from the second learning model.

6. The information processing method according to claim 5, further comprising:
executing, in the first device, processing of outputting a relearning instruction of the first learning models based on an estimation result using the second learning model.

7. The information processing method according to claim 5, further comprising:
outputting a correction value for correcting an arithmetic result by the first learning models based on an arithmetic result by the second learning model.

8. The information processing method according to claim 5, further comprising:
extracting a second feature value of the time series data for each substrate processing apparatus; and
outputting the extracted second feature value to a second device outside the substrate processing apparatus.

9. The information processing method according to claim 8, further comprising:
executing, in the second device,
processing of storing the second feature value extracted for each substrate processing apparatus,
processing of performing learning of a third learning model that outputs the information relating to the substrate processing apparatus in a case where the second feature value is input based on the stored second feature value, and
processing of inputting a newly acquired second feature value into a third learning model after learning to output an estimation result based on information obtained from the third learning model.

10. The information processing method according to claim 9, further comprising:
executing, in the second device,
processing of outputting a relearning instruction of the first learning model s or the second learning model based on an estimation result using the third learning model.

11. The information processing method according to claim 9, further comprising:
outputting a correction value for correcting an arithmetic result by the first learning models or the second learning model based on an arithmetic result by the third learning model.

12. The information processing method according to claim 1, further comprising:
introducing one of the learned first learning models to a new substrate processing apparatus in a case where the new substrate processing apparatus is installed.

13. The information processing method according to claim 1, further comprising:
displaying a performance of each learning model in a list.

14. An information processing apparatus comprising:
an acquisitor configured to acquire time series data from a plurality of types of sensors having different sampling periods provided in a substrate processing apparatus;
a learner configured to perform learning of first learning models that output information relating to the substrate processing apparatus in a case where the time series data from the sensors are input, using each of the pieces of time series data having different sampling periods for each of the sensors individually; and
an estimator configured to input the time series data from the sensors into the corresponding first learning models after learning to output an estimation result based on information obtained from the first learning models.

15. A substrate processing system comprising:
a plurality of substrate processing apparatuses configured to include edge devices connected to sensors and a host device connected to the edge devices, and execute substrate processing inside a chamber; and
an apparatus group server communicably connected to the plurality of substrate processing apparatuses, wherein
each of the edge devices includes
an acquisitor configured to acquire time series data from one of a plurality of types of sensors having different sampling periods,
a first learner configured to perform learning of a first learning model that outputs information relating to the substrate processing apparatus on which the sensor is provided in a case where the time series data from the one of a plurality of types of sensors is input based on the acquired time series data,
a first estimator configured to input the time series data from the one of a plurality of types of sensors into the first learning model after learning to output an estimation result based on information obtained from the first learning model, and
an output configured to output a first feature value extracted from the time series data to the host device,
the host device includes
a first feature value storage configured to store the first feature value input from the edge device,
a second learner configured to perform learning of a second learning model that outputs the information relating to the substrate processing apparatus in a case where the first feature value is input based on the stored first feature value,
a second estimator configured to input a newly acquired first feature value into a second learning model after learning to output an estimation result based on information obtained from the second learning model, and
a transmitter configured to transmit a second feature value of the time series data extracted for each substrate processing apparatus to the apparatus group server, and
the apparatus group server includes
a second feature value storage configured to store the second feature value received from the host device,
a third learner configured to perform learning of a third learning model that outputs the information relating to the substrate processing apparatus in a case where the second feature value is input based on the stored second feature value, and
a third estimator configured to input a newly acquired second feature value to a third learning model after the learning to output an estimation result based on information obtained from the third learning model.

16. The substrate processing system according to claim 15, wherein
the host device and the apparatus group server include
a determiner configured to determine whether or not it is necessary to update the first learning model based on an estimation result by a learning model provided in each of the host device and the apparatus group server, and
an instructor configured to instruct the edge device to relearn the first learning model in a case where it is determined that an update is necessary.
